(19) United States
(12) Patent Application Publication
(10) Pub. No.: US 2015/0171153 A1
(43) Pub. Date: Jun. 18, 2015

(54) ORGANIC LIGHT EMITTING DISPLAY DEVICE

(71) Applicant: Samsung Display Co., Ltd., Yongin-city (KR)

(72) Inventors: Ju-Won Yoon, Yongin-city (KR); Seung-Min Lee, Yongin-city (KR); Il-Jeong Lee, Yongin-city (KR); Jeong-Ho Lee, Yongin-city (KR); Choong-Youl Im, Yongin-city (KR); Su-Yeon Sim, Yongin-city (KR)

(21) Appl. No.: 14/535,039

(22) Filed: Nov. 6, 2014

(30) Foreign Application Priority Data
Dec. 16, 2013 (KR) 10-2013-0156447

(51) Int. Cl. H01L 27/32; H01L 51/52; H01L 27/12

(52) U.S. Cl. CPC H01L 27/3265; H01L 27/3262; H01L 27/1225; H01L 51/5215; H01L 51/5218; H01L 2251/558

(57) ABSTRACT

An organic light emitting display device includes a substrate, an active layer on the substrate, a first insulating layer on the substrate and the active layer, a gate electrode on the first insulating layer, a second insulating layer on and patterned to expose the first insulating layer, a source and a drain electrode on the second insulating layer and in contact with the active layer via contact holes in the second and the first insulating layers, a first electrode on the first insulating layer such that the first electrode is in contact with the source or the drain electrode, and including a transparent conductive layer and a transflective conductive layer, a third insulating layer on the second insulating layer, and patterned to expose the first electrode, an organic thin film layer on the exposed first electrode, and a second electrode on the organic thin film layer.

### CROSS-REFERENCE TO RELATED APPLICATIONS

This application claims priority to, and the benefit of, Korean Patent Application No. 10-2013-0156447, filed on Dec. 16, 2013, in the Korean Intellectual Property Office, the entire contents of which are incorporated herein by reference in their entirety.

### BACKGROUND

1. Field

Embodiments of the present invention relate to a bottom emission-type organic light emitting display device.

2. Description of the Related Technology

When a predetermined voltage is applied to an anode electrode and a cathode electrode of an organic light emitting diode, holes injected through the anode electrode and electrons injected through the cathode electrode are recombined in an organic light emitting layer of the organic light emitting diode, and light is emitted by an energy difference generated in this process.

Since an organic light emitting diode is self-luminous, an organic light emitting display device may be manufactured to have a bottom emission structure in which emitted light moves toward a substrate in which a thin film transistor (TFT) is formed, and a top emission structure in which emitted light moves upwardly from an upper portion of a TFT.

In the bottom emission structure, since light moves toward the substrate in which a TFT is formed, a wiring part including a TFT is excluded from a display region, while in the top emission structure, light is emitted upwardly from a TFT, a relatively large display region may be secured.

Nonetheless, the top emission structure requires a larger number of masks during a manufacturing process, relative to the bottom emission structure, and thus, recently, the bottom emission structure is favorably employed in terms of reducing manufacturing cost.

### SUMMARY OF CERTAIN INVENTIVE ASPECTS

An embodiment of the present invention relates to an organic light emitting display device capable of reducing manufacturing cost.

An embodiment of the present invention relates to an organic light emitting display device capable of enhancing luminous efficiency and reliability.

An embodiment of an organic light emitting display device includes: a substrate; an active layer disposed on the substrate and including a source region, a channel region, and a drain region; a first insulating layer disposed on the substrate and the active layer; a gate electrode disposed on the first insulating layer; a second insulating layer disposed on the first insulating layer and patterned to expose the first insulating layer in a light emitting region; a source electrode and a drain electrode disposed on the second insulating layer and disposed to be in contact with the active layer via contact holes formed in the second insulating layer and the first insulating layer; a first electrode disposed on the first insulating layer of the light emitting region such that the first electrode is in contact with at least one of the source electrode or the drain electrode, and including a transparent conductive layer and a transflective conductive layer; a third insulating layer disposed on the second insulating layer, and patterned to expose the first electrode in the light emitting region; an organic thin film layer disposed on the exposed first electrode of the light emitting region; and a second electrode disposed on the organic thin film layer.

An embodiment of an organic light emitting display device includes: a substrate; an active layer disposed on the substrate and including a source region, a channel region, and a drain region; a first insulating layer disposed on the substrate and the active layer; a gate electrode disposed on the first insulating layer; a second insulating layer disposed on the first insulating layer and patterned to expose the first insulating layer in a light emitting region; a source electrode and a drain electrode disposed on the second insulating layer, disposed to be in contact with the active layer via contact holes formed in the second insulating layer and the first insulating layer, and including a transparent conductive layer and a transflective conductive layer; a first electrode disposed on the first insulating layer of the light emitting region such that the first electrode is in contact with at least one of the source electrode or the drain electrode, and including a transparent conductive layer and a transflective conductive layer; a third insulating layer disposed on the second insulating layer, and patterned to expose the first electrode in the light emitting region; an organic thin film layer disposed on the exposed first electrode of the light emitting region; and a second electrode disposed on the organic thin film layer.

The substrate may include one of glass, quartz, and a resin having transmittance more than or equal to about 90%.

The active layer may include polysilicon or an oxide semiconductor. The oxide semiconductor may include a zinc oxide (ZnO), and may be doped with ions of at least one of gallium (Ga), indium (In), tin (Sn), zirconium (Zr), hafnium (Hf), or vanadium (V).

The organic light emitting display device may further include: a lower electrode of a capacitor formed of the active layer on the substrate on a side of the active layer; and an upper electrode of the capacitor disposed to overlap with the lower electrode on the first insulating layer on a side of the gate electrode.

The organic light emitting display device may further include: a pad part disposed on the second insulating layer on a side of the source electrode or the drain electrode, wherein the pad part may include a conductive layer including a same material as the source electrode, the drain electrode, the transparent conductive layer and the transflective conductive layer.

The transparent conductive layer may include one of indium tin oxide (ITO), indium zinc oxide (IZO), indium tin zinc oxide (ITZO), and tungsten-doped indium oxide (IWO) having transmittance greater than or equal to about 90%.

The transflective conductive layer may include one of metals among aluminum (Al), nickel (Ni), or lanthanum (La) having reflectivity ranging from about 5% to about 60%, or an alloy thereof, and may be formed as having a thickness ranging from about 10 Å to about 500 Å.

The first electrode may be formed by stacking the transparent conductive layer, the transflective conductive layer, and the transparent conductive layer. The second electrode may include a metal having a work function lower than that of the first electrode, or an alloy including the metal. The metal may include one of aluminum (Al), silver (Ag), gold (Au), platinum (Pt), or magnesium (Mg).

### BRIEF DESCRIPTION OF THE DRAWINGS

Certain embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will full convey the scope of certain embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals generally refer to like elements throughout.

FIG. 1 is a cross-sectional view illustrating an organic light emitting display device according to an embodiment of the present invention;

FIG. 2 is a cross-sectional view illustrating an organic light emitting display device according to another embodiment of the present invention;

FIGS. 3A through 3G are cross-sectional views illustrating a method for manufacturing an organic light emitting display device according to an embodiment of the present invention; and

FIGS. 4A through 4G are cross-sectional views illustrating a method for manufacturing an organic light emitting display device according to another embodiment of the present invention.

### DETAILED DESCRIPTION OF CERTAIN INVENTIVE EMBODIMENTS

Hereinafter, certain embodiments of the present invention will be described in detail with reference to the accompanying drawings. These embodiments are provided for a person skilled in the art to fully understand the present invention, may be modified, and the scope of the present invention is not limited to the embodiments described hereinafter.

FIG. 1 is a cross-sectional view illustrating an organic light emitting display device according to an embodiment of the present invention.

Referring to FIG. 1, a substrate 10 includes a display region D and a peripheral region P. The display region D is a region in which an image is displayed and on which a plurality of pixels are formed. A pixel is a light emitting element including an organic light emitting diode (OLED), at least one of a thin film transistor (TFT) for transmitting a signal to the OLED or driving the OLED, and at least one capacitor for maintaining the signal. The peripheral region P is peripheral to the display region D, in which a pad part for receiving a signal from the outside and a circuit unit for driving a plurality of pixels are formed.

An active layer 14a of the TFT is formed on the substrate 10. The active layer 14a may include polysilicon or an oxide semiconductor, and includes a source region, a channel region, and a drain region.

A lower electrode 14b of the capacitor may be formed on one side of the active layer 14a. The lower electrode 14b of the capacitor may include a material identical to that of the active layer 14a, or may be formed on the same layer and may be doped with impurity ions to have conductivity higher than the active layer 14a.

In one embodiment, a buffer layer 12 is formed on the substrate 10, and the active layer 14a and the lower electrode 14b may be formed on the buffer layer 12.

A first insulating layer 16 is formed on the substrate 10 including the active layer 14a and the lower electrode 14b. The first insulting layer 16 is used as a gate insulating layer of the TFT.

A gate electrode 18 is formed on the first insulating layer 16 above the channel region, and an upper electrode 19 of the capacitor may be formed on the first insulating layer 16 on one side of the gate electrode 18 such that the upper electrode 19 overlaps with the lower electrode 14b.

A second insulating layer 20 is formed on the first insulating layer 16 including the gate electrode 18 and the upper electrode 19. An opening is formed in the second insulating layer 20 such that the first insulating layer 16 of a light emitting region is exposed, and contact holes are formed in the second insulating layer 20 and the first insulating layer 16 such that the source region and the drain region of the active layer 14a are exposed.

Source and drain electrodes 22 are formed on the second insulating layer 20 such that they are coupled with the source region and the drain region of the active layer 14a through the contact holes. A first electrode 26 is formed on the first insulating layer 16 exposed through the opening such that the first electrode 26 is connected to the source or drain electrode 22.

The first electrode 26 may be used as an anode electrode of the OLED and may include transparent conductive layers 26a and a transflective conductive layer 26b. For example, the first electrode 26 may have a structure in which the transparent conductive layer 26a and the transflective conductive layer 26b are stacked, or may have a structure in which the transparent conductive layer 26a, the transflective conductive layer 26b, and the transparent conductive layer 26a are stacked.

During the process of forming the source and drain electrodes 22, the pad part 27 may be formed on the second insulating layer 20 of the peripheral region P. The pad part 27 may include a conductive layer 24 including a material identical to that of the source and drain electrodes 22, and a structure in which a transparent conductive layer 26a, a transflective conductive layer 26b, and a transparent conductive layer 26a are stacked.

A third insulating layer 28 is formed on the second insulating layer 20 including the source and drain electrodes 22, the first electrode 26, and the pad part 27, and openings are formed in the third insulating layer 28 such that the first electrode 26 of the light emitting region and a predetermined portion of the pad part 27 are exposed.

An organic thin film layer 30 is formed on the exposed first electrode 26 in the light emitting region, and a second electrode 32 is formed on the organic thin film layer 30, thus completing an OLED composed of the first electrode 26, the organic thin film layer 30, and the second electrode 32.

The organic thin film layer 30 may include one or more of a hole injecting layer, a hole transport layer, an emission layer, an electron transport layer, and an electron injecting layer. The second electrode 32 may be formed as a common electrode on the third insulating layer 28 in the entire display region D.

In a case in which light produced in the organic thin film layer 30 is emitted to a bottom surface of the substrate 10 through the first electrode 26, a bottom emission structure OLED device may be implemented.

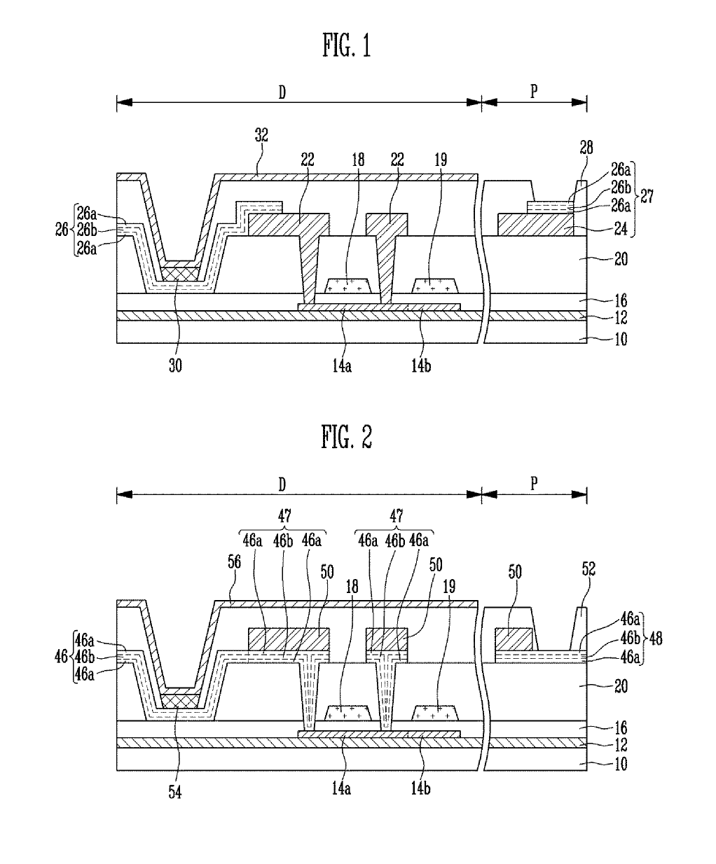

FIG. 2 is a cross-sectional view illustrating an organic light emitting display device according to another embodiment of the present invention.

Referring to FIG. 2, a substrate 10 includes a display region D and a peripheral region P. The display region D is a region in which an image is displayed and on which a plurality of pixels are formed. A pixel is a light emitting element including an organic light emitting diode (OLED), at least one of a thin film transistor (TFT) for transmitting a signal to the OLED or driving the OLED, and at least one capacitor for maintaining the signal. The peripheral region P is peripheral to the display region D, in which a pad part for receiving a signal from the outside and a circuit unit for driving a plurality of pixels are formed.

An active layer 14a of the TFT is formed on the substrate 10. The active layer 14a may be include polysilicon or an oxide semiconductor and includes a source region, a channel region, and a drain region.

A lower electrode 14b of the capacitor may be formed on one side of the active layer 14a. The lower electrode 14b of the capacitor may include a material identical to that of the active layer 14a, or may be formed on the same layer and may be doped with impurity ions to have conductivity higher than the active layer 14a.

In one embodiment, a buffer layer 12 is formed on the substrate 10, and the active layer 14a and the lower electrode 14b may be formed on the buffer layer 12.

A first insulating layer 16 is formed on the substrate 10 including the active layer 14a and the lower electrode 14b. The first insulting layer 16 is used as a gate insulating layer of the TFT.

A gate electrode 18 is formed on the first insulating layer 16 above the channel region, and an upper electrode 19 of the capacitor may be formed on the first insulating layer 16 on one side of the gate electrode 18 such that the upper electrode 19 overlaps with the lower electrode 14b.

A second insulating layer 20 is formed on the first insulating layer 16 including the gate electrode 18 and the upper electrode 19. An opening is formed in the second insulating layer 20 such that the first insulating layer 16 of a light emitting region is exposed, and contact holes are formed in the second insulating layer 20 and the first insulating layer 16 such that the source region and the drain region of the active layer 14a are exposed.

Source and drain electrodes 47 are formed on the second insulating layer 20 such that they are coupled with the source region and the drain region of the active layer 14a through the contact holes. A first electrode 46 is formed on the first insulating layer 16 exposed through the opening such that the first electrode 46 of the OLED is coupled with the source or drain electrode 47.

The source and drain electrodes 47 and the first electrode 46 may include transparent conductive layers 46a and a transflective conductive layer 46b. For example, the source and drain electrodes 47 and the first electrode 46 may have a structure in which the transparent conductive layer 46a and the transflective conductive layer 46b are stacked, or may have a structure in which the transparent conductive layer 46a, the transflective conductive layer 46b, and the transparent conductive layer 46a are stacked.

During the process of forming the source and drain electrodes 47 and the first electrode 46, a pad part 48 may be formed on the second insulating layer 20 of the peripheral region P. The pad part 48 may include materials identical to those of the source and drain electrodes 47, or include layers identical to those of the source and drain electrodes 47, for example, may have a structure in which a transparent conductive layer 46a, a transflective conductive layer 46b, and a transparent conductive layer 46a are stacked.

A metal layer 50 may be formed on the source and drain electrodes 47 and the pad part 48. The metal layer 50 may include a metal such as, for example, at least one of aluminum (Al), molybdenum (Mo), tungsten (W), and nickel (Ni), or an alloy.

A third insulating layer 52 is formed on the second insulating layer 20 including the source and drain electrodes 47, the first electrode 46, and the pad part 48, and openings are formed in the third insulating layer 52 such that the first electrode 46 of the light emitting region and a predetermined portion of the pad part 48 are exposed.

An organic thin film layer 54 is formed on the exposed first electrode 46 in the light emitting region, and a second electrode 56 is formed on the organic thin film layer 54, thus completing an OLED composed of the first electrode 46, the organic thin film layer 54, and the second electrode 56.

The organic thin film layer 54 may include one or more of a hole injecting layer, a hole transport layer, an emission layer, an electron transport layer, and an electron injecting layer. The second electrode 56 may be formed as a common electrode on the third insulating layer 52 in the entire display region D.

In a case in which light produced in the organic thin film layer 54 is emitted to a bottom surface of the substrate 10 through the first electrode 46, a bottom emission structure OLED device may be implemented.

Hereinafter, an embodiment will be described in detail through a method for manufacturing an organic light emitting display device.

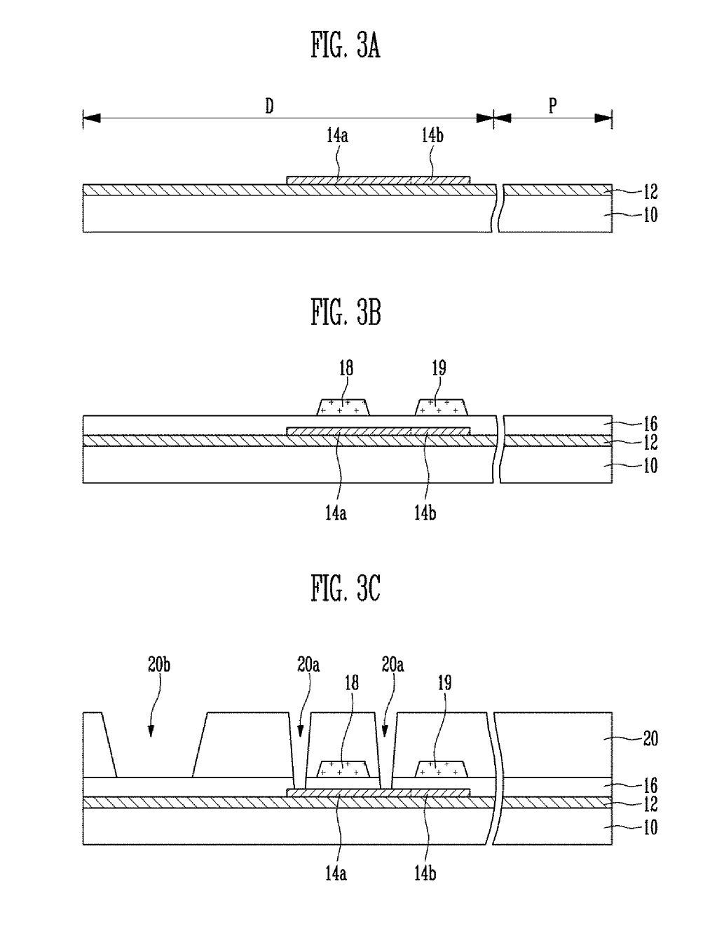

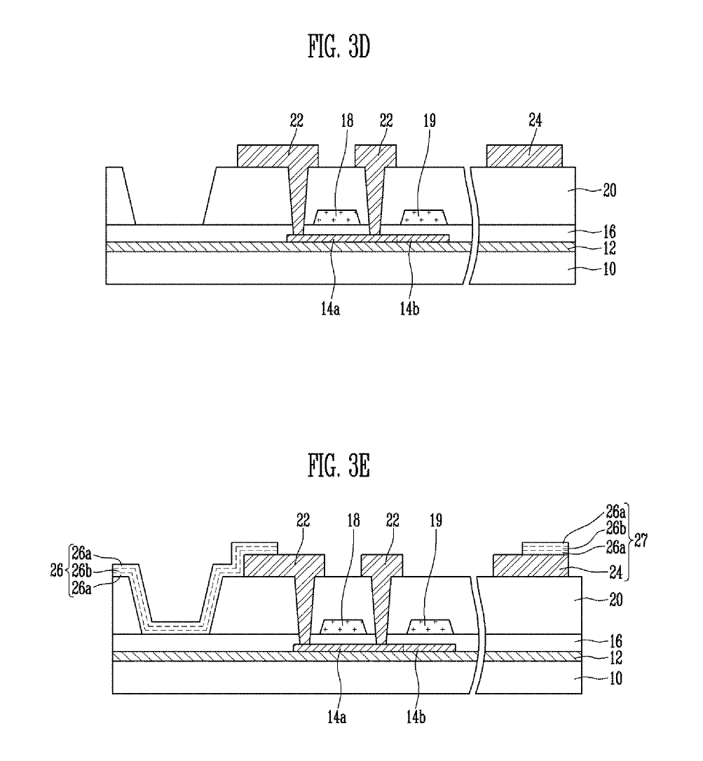

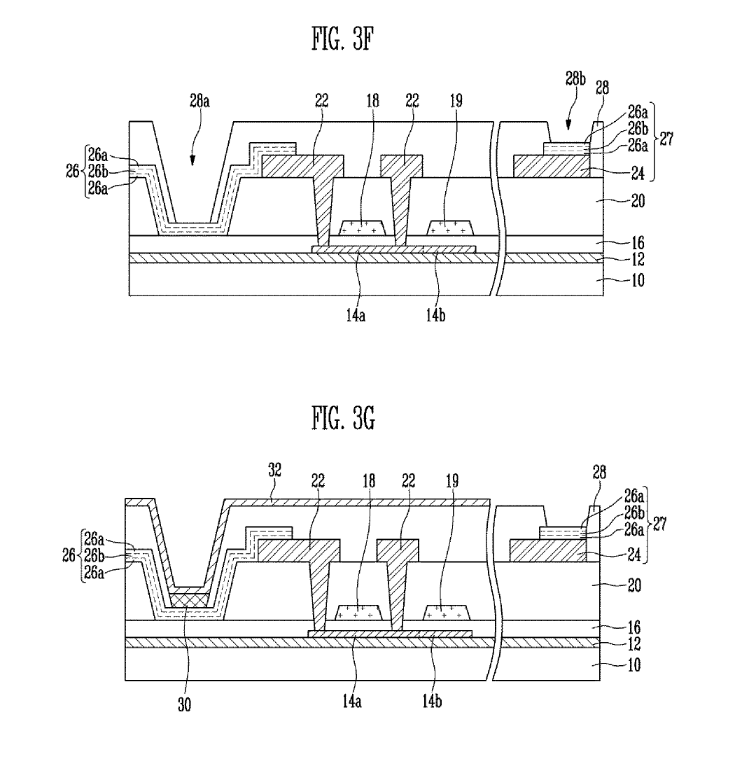

FIGS. 3A through 3G are cross-sectional views illustrating a method for manufacturing an organic light emitting display device according to an embodiment of the present invention.

Referring to FIG. 3A, the substrate 10 in which the display region D and the peripheral region P are defined is prepared. The substrate 10 is a transparent substrate and may include one of glass, quartz, and a resin having transmittance more than or equal to about 90%.

The buffer layer 12 is formed on the substrate 10. The buffer layer 12 includes a silicon oxide film (SiOx) or a silicon nitride film (SiNx). A semiconductor layer is formed on the buffer layer 12. The semiconductor layer is patterned through a photolithography process using a first mask to form the active layer 14a of a TFT and the lower electrode 14b of a capacitor on the substrate 10 of the display region D. The lower electrode 14b may have conductivity higher than that of the active layer 14a, and thus, after the lower electrode 14b is formed, it may be doped with impurity ions.

The semiconductor layer may include polysilicon or an oxide semiconductor. The oxide semiconductor may include, for example, indium oxide (ZnO) and may be doped with ions of at least one of gallium (Ga), indium (In), tin (Sn), zirconium (Zr), hafnium (Hf), and vanadium (V).

Referring to FIG. 3B, the first insulating layer 16 and a conductive layer are formed on the substrate 10 including the active layer 14a and the lower electrode 14b. The conductive layer is patterned through a photolithography process using a second mask to form the gate electrode 18 on the first insulating layer above the channel region and the upper electrode 19 of the capacitor on the first insulating layer 16 that overlaps with the lower electrode 14b.

The first insulating layer 16 is a gate insulating layer of a TFT and may include a silicon oxide film (SiOx), silicon nitride film (SiNx), or the like. The conductive layer may include polysilicon or metal.

In one embodiment, the case in which the gate electrode 18 and the upper electrode 19 are formed of the same conductive layer has been described, but, the gate electrode 18 and the upper electrode 19 may be formed of different conductive layers. In this case, a mask needs to be additionally used.

Referring to FIG. 3C, the second insulating layer 20 is formed on the first insulating layer 16 including the gate electrode 18 and the upper electrode 19. The second insulating layer 20 is patterned through a photolithography process using a third mask to form an opening 20b exposing the first insulating layer 16 in the light emitting region, and the first insulating layer 16 is further patterned to form contact holes 20a exposing source and drain regions of the active layer 14a.

Referring to FIG. 3D, a conductive layer is formed on the second insulating layer 20 to bury the contact hole 20a. The conductive layer is patterned through a photolithography process using a fourth mask to form the source and drain electrodes 22 connected to the source and drain regions of the active layer 14a via the contact holes 20a.

During the process of forming the source and drain electrodes 22, a conductive layer 24 may be formed on the second insulating layer in the peripheral region D.

Referring to FIG. 3E, the transparent conductive layer 26a and the transflective conductive layer 26b are stacked, or the transparent conductive layer 26a, the transflective conductive layer 26b, and the transparent conductive layer 26a are stacked, on the second insulating layer 20 including the source and drain electrodes 22 and the conductive layer 24 and the first insulating layer 16. The transparent conductive layer 26a and the transflective conductive layer 26b are patterned through a photolithography process using a fifth mask to form the first electrode 26 of the OLED connected to the source or drain electrode 22 on the exposed first insulating layer 12 of the opening 20b and the pad part 27 in which the conductive layer 24, the transparent conductive layer 26a, the transflective conductive layer 26b, and the transparent conductive layer 26a are stacked in the peripheral region P.

The transparent conductive layer 26a may be include, for example, one of indium tin oxide (ITO), indium zinc oxide (IZO), indium tin zinc oxide (ITZO), and tungsten-doped indium oxide (IWO) having transmittance greater than or equal to about 90% in a wavelength (ranging from about 400 nm to about 700 nm, for example) of a visible light region.

The transflective conductive layer 26b may include aluminum (Al), nickel (Ni), or lanthanum (La) having reflectivity ranging from about 5% to about 60%, or an alloy thereof, and may be formed to have a thickness ranging from about 10 Å to about 500 Å. In order to act as a half-mirror, reflectivity and thickness of the transflective conductive layer 26b may be from about 20% to about 50% and from about 100 Å to about 300 Å, respectively.

Referring to FIG. 3F, the third insulating layer 28 is formed on the second insulating layer 20 including the source and drain electrodes 22, the first electrode 26, and the pad part 27. The third insulating layer 28 is patterned through a photolithography process using a sixth mask to form an opening 28a exposing the first electrode 26 and an opening 28b exposing a predetermined portion of the pad part 27.

Referring to FIG. 3G, the organic thin film layer 30 is formed on the exposed first electrode 26 in the opening 28a, and the second electrode 32 is formed on the organic thin film layer 30. Accordingly, an OLED composed of the first electrode 26, the organic thin film layer 30, and the second electrode 32 is completed.

The organic thin film layer 30 may include one or more of a hole injecting layer, a hole transport layer, an emission layer, an electron transport layer, and an electron injecting layer. The second electrode 32 may be formed as a common electrode on the third insulating layer 28 in the entire display region D, and may include a metal having a work function lower than that of the first electrode 26, or an alloy including the metal. The metal may include, for example, aluminum (Al), silver (Ag), gold (Au), platinum (Pt), magnesium (Mg), or the like.

In a case in which the first electrode 26 acts as a half-mirror, the second electrode 32 has high reflectivity greater than or equal to about 80%.

In the foregoing embodiment, in a case in which the first electrode 26 is configured as an anode electrode of the OLED, the first electrode 26 may have a structure in which the transparent conductive layer 26a and the transflective conductive layer 26b are stacked. Since the transflective conductive layer 26b acts as a half-mirror, light emission efficiency may be increased due to a resonance effect between the first and second electrodes 26 and 32, and color purity and color characteristics may be enhanced to improve image quality.

In the foregoing embodiment, the pad part 27 is formed as having a structure in which the transparent conductive layer 26a and the transflective conductive layer 26b are stacked. In this case, since the pad part 27 is formed during the process of forming the first electrode 26 using a mask, one mask may be saved and manufacturing cost may be reduced. Since the organic light emitting display device is manufactured by using six or seven masks, the number of masks may be reduced, relative to the related art.

In addition, since the transparent conductive layer 26a of the pad part 27 is in contact with a wiring, a degradation of conductivity and reliability due to corrosion of the pad part 27, or the like, may be prevented.

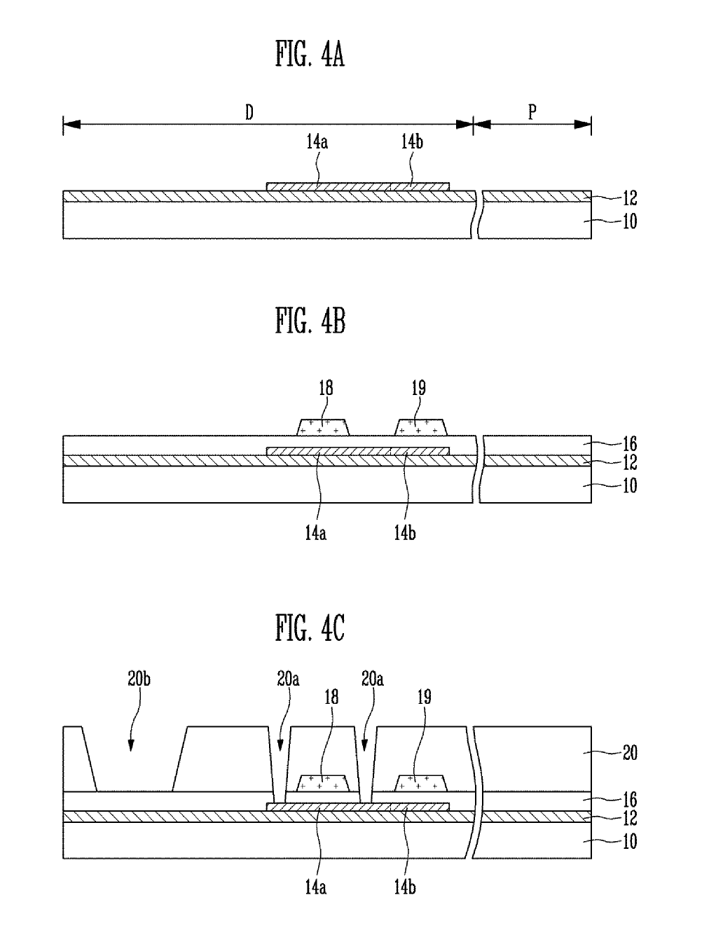

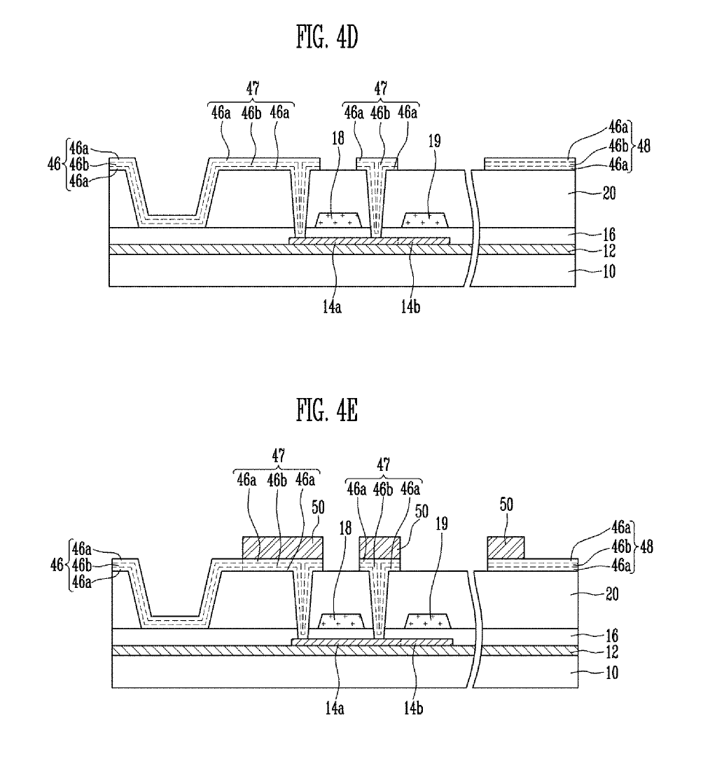

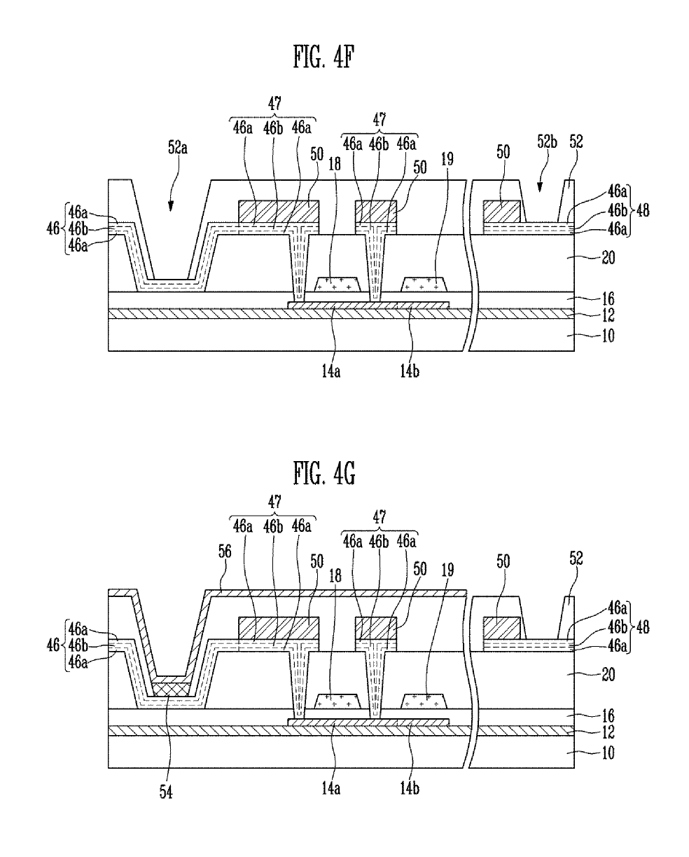

FIGS. 4A through 4G are cross-sectional views illustrating a method for manufacturing an organic light emitting display device according to another embodiment of the present invention.

Referring to FIG. 4A, the substrate 10 in which the display region D and the peripheral region P are defined is prepared. The substrate 10 is a transparent substrate and may include one of glass, quartz, and a resin having transmittance more than or equal to about 90%.

The buffer layer 12 is formed on the substrate 10. The buffer layer 12 includes a silicon oxide film (SiOx) or a silicon nitride film (SiNx). A semiconductor layer is formed on the buffer layer 12. The semiconductor layer is patterned through a photolithography process using a first mask to form the active layer 14a of a TFT and the lower electrode 14b of a capacitor on the substrate 10 of the display region D. The lower electrode 14b may have conductivity higher than that of the active layer 14a, and thus, after the lower electrode 14b is formed, it may be doped with impurity ions.

The semiconductor layer may include polysilicon or an oxide semiconductor. The oxide semiconductor may include, for example, indium oxide (ZnO) and may be doped with ions of at least one of gallium (Ga), indium (In), tin (Sn), zirconium (Zr), hafnium (Hf), and vanadium (V).

Referring to FIG. 4B, the first insulating layer 16 and a conductive layer are formed on the substrate 10 including the active layer 14a and the lower electrode 14b. The conductive layer is patterned through a photolithography process using a second mask to form the gate electrode 18 on the first insulating layer above the channel region and the upper electrode 19 of the capacitor on the first insulating layer 16 that overlaps with the lower electrode 14b.

The first insulating layer 12 is a gate insulating layer of a TFT and may include a silicon oxide film (SiOx), silicon nitride film (SiNx), or the like. The conductive layer may include polysilicon or metal.

In one embodiment, the case in which the gate electrode 18 and the upper electrode 19 are formed of the same conductive layer has been described, but, the gate electrode 18 and the upper electrode 19 may be formed as different conductive layers. In this case, a mask needs to be additionally used.

Referring to FIG. 4C, the second insulating layer 20 is formed on the first insulating layer 16 including the gate electrode 18 and the upper electrode 19. The second insulating layer 20 is patterned through a photolithography process using a third mask to form an opening 20b exposing the first insulating layer 16 in the light emitting region, and the first insulating layer 16 is further patterned to form contact holes 20a exposing source and drain regions of the active layer 14a.

Referring to FIG. 4D, the transparent conductive layer 46a and the transflective conductive layer 46b are stacked, or the transparent conductive layer 46a, the transflective conductive layer 46b, and the transparent conductive layer 46a are stacked, on the second insulating layer 20 and the first insulating layer 16. The transparent conductive layer 46a and the transflective conductive layer 46b are patterned through a photolithography process using a fourth mask to form the source and drain electrodes 47 connected to the source region and the drain region of the active layer 14a via the contact hole 20a on the second insulating layer 20, the first electrode 46 of the OLED on the exposed first insulating layer 12 of the opening 20b, and the pad part 48 in the peripheral region P. In this case, the source and drain electrodes 47 and the first electrode 46 may be formed to be connected.

The transparent conductive layer 46a may include one of ITO, IZO, ITZO, and IWO having transmittance greater than or equal to about 90% in a wavelength (ranging from about 400 nm to about 700 nm, for example) of a visible light region.

The transflective conductive layer 46b may be formed of any one of metals among aluminum (Al), nickel (Ni), and lanthanum (La) having reflectivity ranging from about 5% to about 60%, or an alloy thereof, and may be formed as having a thickness ranging from about 10 Å to about 50 Å. In order to act as a half-mirror, reflectivity and thickness of the transflective conductive layer 26b may be set from about 20% to about 50% and from about 100 Å to about 300 Å, respectively.

Referring to FIG. 4E, a metal layer is formed on the second insulating layer 20 including the source and drain electrodes 47, the first electrode 46, and the pad part 48. The metal layer is patterned through a photolithography process using a fifth mask to form the metal layers 50 on the source and drain electrodes 47, the first electrode 46, and the pad part 48.

In one embodiment, the case in which the source and drain electrodes 47, the first electrode 46, and the metal layer 50 are formed, separately, has been described. However, after the transparent conductive layer 46a, the transflective conductive layer 46b, and the metal layer 50 are sequentially stacked, for example, the metal layer 50, the transparent conductive layer 46a, and the transflective conductive layer 46b may be sequentially patterned through a photolithography process using a half-tone mask to form the source and drain electrodes 47, the first electrode 46, and the metal layer 50. In this case, one mask may be saved.

In the case in which the source and drain electrodes 47, the first electrode 46, and the pad part 48 are formed as having the transparent conductive layer 46a and the transflective conductive layer 46b, they are so thin, having a high resistance value. Thus, by forming the metal layer 50 on the source and drain electrodes 47, the first electrode 46, and the pad part 48, a resistance value thereof may be effectively reduced.

Referring to FIG. 4F, the third insulating layer 52 is formed on the second insulating layer 20 including the source and drain electrodes 47, the first electrode 46, and the pad part 48. The third insulating layer 52 is patterned through a photolithography process using a sixth mask to form an opening 52a exposing the first electrode 46 and an opening 52b exposing a predetermined portion of the pad part 48.

Referring to FIG. 4G, the organic thin film layer 54 is formed on the exposed first electrode 46 in the opening 52a, and the second electrode 56 is formed on the organic thin film layer 54. Accordingly, an OLED composed of the first electrode 46, the organic thin film layer 54, and the second electrode 56 is completed.

The organic thin film layer 54 may include at least one of a hole injecting layer, a hole transport layer, an emission layer, an electron transport layer, and an electron injecting layer. The second electrode 56 may be formed as a common electrode on the third insulating layer 52 in the entire display region D, and may include a metal having a work function lower than that of the first electrode 46 or an alloy including the metal. The metal may include aluminum (Al), silver (Ag), gold (Au), platinum (Pt), magnesium (Mg), or the like.

In a case in which the first electrode 46 acts as a half-mirror, the second electrode 56 has high reflectivity greater than or equal to about 80%.

In the foregoing embodiment, the first electrode 46 is formed to have a structure in which the transparent conductive layer 46a and the transflective conductive layer 46b are stacked, as an anode electrode of the OLED. Since the transflective conductive layer 46b acts as a half-mirror, light emission efficiency may be increased due to a resonance effect between the first and second electrodes 46 and 56, and color purity and color characteristics may be enhanced to improve image quality.

In the foregoing embodiment, the first electrode 46, the source and drain electrodes 47, and the pad part 48 are formed as having a structure in which the transparent conductive layer 46a and the transflective conductive layer 46b are stacked. In this case, since the first electrode 46, the source and drain electrodes 47, and the pad part 48 are simultaneously formed using a mask, one mask may be saved and manufacturing cost may be reduced.

Since the organic light emitting display device is manufactured by using five or six masks, the number of masks may be reduced, relative to the related art.

In addition, since the transparent conductive layer 46a of the pad part 48 is in contact with a wiring, a degradation of conductivity and reliability due to corrosion of the pad part 48, or the like, may be prevented.

The first electrode of an OLED is formed to have the stacked structure of the transparent conductive layer and the transflective conductive layer. Since the transflective conductive layer acts as a half-mirror, light emission efficiency may be increased due to a resonance effect between the first and second electrodes, and since color purity and color characteristics are enhanced, image quality may be improved.

Also, the pad part is formed to have the stacked structure of the transparent conductive layer and the transflective conductive layer. Since the pad part may be formed together during the process of forming the first electrode by using a mask, one mask may be saved and manufacturing cost may be reduced. In addition, since the transparent conductive layer of the pad part is in contact with a wiring, a degradation of conductivity and reliability due to corrosion of the pad part, or the like, may be prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light emitting display device comprising:
a substrate;
an active layer disposed on the substrate and including a source region, a channel region, and a drain region;
a first insulating layer disposed on the substrate and the active layer;
a gate electrode disposed on the first insulating layer;
a second insulating layer disposed on the first insulating layer and patterned to expose the first insulating layer in a light emitting region;
a source electrode and a drain electrode disposed on the second insulating layer and disposed to be in contact with the active layer via contact holes formed in the second insulating layer and the first insulating layer;
a first electrode disposed on the first insulating layer of the light emitting region such that the first electrode is in contact with at least one of the source electrode or the drain electrode, and including a transparent conductive layer and a transflective conductive layer;
a third insulating layer disposed on the second insulating layer, and patterned to expose the first electrode in the light emitting region;
an organic thin film layer disposed on the exposed first electrode of the light emitting region; and
a second electrode disposed on the organic thin film layer.

2. The organic light emitting display device of claim 1, wherein the substrate includes one of glass, quartz, and a resin having transmittance more than or equal to about 90%.

3. The organic light emitting display device of claim 1, wherein the active layer comprises polysilicon or an oxide semiconductor.

4. The organic light emitting display device of claim 3, wherein the oxide semiconductor comprises a zinc oxide (ZnO).

5. The organic light emitting display device of claim 4, wherein the oxide semiconductor is doped with ions of at least one of gallium (Ga), indium (In), tin (Sn), zirconium (Zr), hafnium (Hf), or vanadium (V).

6. The organic light emitting display device of claim 1, further comprising:
a lower electrode of a capacitor formed of the active layer on the substrate on a side of the active layer; and
an upper electrode of the capacitor disposed to overlap with the lower electrode on the first insulating layer on a side of the gate electrode.

7. The organic light emitting display device of claim 1, further comprising:
a pad part disposed on the second insulating layer on a side of the source electrode or the drain electrode,
wherein the pad part comprises a conductive layer including a same material identical as the source electrode, the drain electrode, the transparent conductive layer and the transflective conductive layer.

8. The organic light emitting display device of claim 1, wherein the transparent conductive layer includes one of indium tin oxide (ITO), indium zinc oxide (IZO), indium tin zinc oxide (ITZO), and tungsten-doped indium oxide (IWO) having transmittance greater than or equal to about 90%.

9. The organic light emitting display device of claim 1, wherein the transflective conductive layer includes one of aluminum (Al), nickel (Ni), or lanthanum (La) having reflectivity ranging from about 5% to about 60%, or an alloy thereof.

10. The organic light emitting display device of claim 1, wherein the transflective conductive layer has a thickness ranging from about 10 Å to about 500 Å.

11. The organic light emitting display device of claim 1, wherein the first electrode is formed by stacking the transparent conductive layer, the transflective conductive layer, and the transparent conductive layer.

12. The organic light emitting display device of claim 1, wherein the second electrode includes a metal having a work function lower than that of the first electrode, or an alloy including the metal.

13. The organic light emitting display device of claim 12, wherein the metal includes one of aluminum (Al), silver (Ag), gold (Au), platinum (Pt), or magnesium (Mg).

14. An organic light emitting display device comprising:
a substrate;
an active layer disposed on the substrate and including a source region, a channel region, and a drain region;
a first insulating layer disposed on the substrate and the active layer;
a gate electrode disposed on the first insulating layer;
a second insulating layer disposed on the first insulating layer and patterned to expose the first insulating layer in a light emitting region;
a source electrode and a drain electrode disposed on the second insulating layer, disposed to be in contact with the active layer via contact holes formed in the second insulating layer and the first insulating layer, and including a transparent conductive layer and a transflective conductive layer;
a first electrode disposed on the first insulating layer of the light emitting region such that the first electrode is in contact with at least one of the source electrode or the drain electrode, and including a transparent conductive layer and a transflective conductive layer;
a third insulating layer disposed on the second insulating layer, and the first electrode, and patterned to expose the first electrode in the light emitting region;
an organic thin film layer disposed on the exposed first electrode of the light emitting region; and
a second electrode disposed on the organic thin film layer.

15. The organic light emitting display device of claim 14, wherein the substrate includes one of glass, quartz, and a resin having transmittance more than or equal to about 90%.

16. The organic light emitting display device of claim 14, wherein the active layer comprises polysilicon or an oxide semiconductor.

17. The organic light emitting display device of claim 16, wherein the oxide semiconductor comprises a zinc oxide (ZnO).

18. The organic light emitting display device of claim 17, wherein the oxide semiconductor is doped with ions of at least one of gallium (Ga), indium (In), tin (Sn), zirconium (Zr), hafnium (Hf), or vanadium (V).

19. The organic light emitting display device of claim 14, further comprising:
a lower electrode of a capacitor formed of the active layer on the substrate on a side of the active layer; and
an upper electrode of the capacitor disposed to overlap with the lower electrode on the first insulating layer on a side of the gate electrode.

20. The organic light emitting display device of claim 14, further comprising:
a pad part disposed on the second insulating layer on a side of the source electrode or the drain electrode,
wherein the pad part comprises the transparent conductive layer, and the transflective conductive layer.

21. The organic light emitting display device of claim 20, further comprising:
metal layers disposed on the source electrode, the drain electrode, and the pad part.

22. The organic light emitting display device of claim 21, wherein the metal layer includes at least one of aluminum (Al), molybdenum (Mo), tungsten (W), or nickel (Ni), or an alloy.

23. The organic light emitting display device of claim 14, wherein the transparent conductive layer includes one of indium tin oxide (ITO), indium zinc oxide (IZO), indium tin zinc oxide (ITZO), and tungsten-doped indium oxide (IWO) having transmittance greater than or equal to about 90%.

24. The organic light emitting display device of claim 14, wherein the transflective conductive layer includes at least one of aluminum (Al), nickel (Ni), or lanthanum (La) having reflectivity ranging from about 5% to about 60%, or an alloy thereof.

25. The organic light emitting display device of claim 14, wherein the transflective conductive layer has a thickness ranging from about 10 Å to about 500 Å.

26. The organic light emitting display device of claim 14, wherein the source electrode, the drain electrode, and the first electrode are formed by stacking the transparent conductive layer, the transflective conductive layer, and the transparent conductive layer.

27. The organic light emitting display device of claim 14, wherein the second electrode includes a metal having a work function lower than that of the first electrode, or an alloy including the metal.

28. The organic light emitting display device of claim 27, wherein the metal includes one of aluminum (Al), silver (Ag), gold (Au), platinum (Pt), or magnesium (Mg).
